(19) United States
(12) Patent Application Publication
(10) Pub. No.: US 2025/0103778 A1
(43) Pub. Date: Mar. 27, 2025

(54) MOLECULE GENERATION USING 3D GRAPH AUTOENCODING DIFFUSION PROBABILISTIC MODELS

(71) Applicant: NEC Laboratories America, Inc., Princeton, NJ (US)

(72) Inventors: Renqiang Min, Princeton, NJ (US); Tianxiao Li, Plainsboro, NJ (US)

(21) Appl. No.: 18/891,687

(22) Filed: Sep. 20, 2024

Related U.S. Application Data
(60) Provisional application No. 63/539,852, filed on Sep. 22, 2023.
(60) Provisional application No. 63/627,099, filed on Jan. 31, 2024.

(51) Int. Cl. G06F 30/27; G06N 7/01

(52) U.S. Cl. CPC G06F 30/27; G06N 7/01

(57) ABSTRACT

Methods and systems for molecule generation include embedding an input template molecule into a latent space to generate a vector. The vector is decoded using a denoising diffusion implicit model (DDIM) to generate a new molecule specification that is based on the input template molecule. The new molecule is produced using the new molecule specification.

### RELATED APPLICATION INFORMATION

This application claims priority to U.S. Patent Application No. 63/539,852, filed on Sep. 22, 2023, and to U.S. Patent Application No. 63/627,099, filed on Jan. 31, 2024, each incorporated herein by reference in its entirety.

### BACKGROUND

### Technical Field

The present invention relates to molecular modeling and, more particularly, to using machine learning models to generate molecules.

### Description of the Related Art

While significant progress has been made in the generation of three-dimensional (3D) molecule models, operating on a defined template molecule is challenging due to a lack of a latent molecular semantic space. In contrast, language models perform very well in generating text because of the existence of a large and diverse corpus of textual training material that can be used to identify semantic similarities between different words, thereby creating a semantic space that can be used to embed text. Thus, a word can be selected that has a similar meaning to an input word by finding words that are close to the input word in the latent semantic space. Lacking such a space for molecular structures makes it difficult to generate molecules based on an input template molecule, for example identifying molecules that are similar to the input template molecule but that are varied toward more desirable characteristics.

### SUMMARY

A method for molecule generation includes embedding an input template molecule into a latent space to generate a vector. The vector is decoded using a denoising diffusion implicit model (DDIM) to generate a new molecule specification that is based on the input template molecule. The new molecule is produced using the new molecule specification.

A system for molecule generation includes a hardware processor and a memory that stores a computer program. When executed by the hardware processor, the computer program causes the hardware processor to embed an input template molecule into a latent space to generate a vector, to decode the vector using a DDIM to generate a new molecule specification that is based on the input template molecule, and to trigger production of the new molecule using the new molecule specification.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is a diagram illustrating the generation of a new molecule based on an input template molecule, in accordance with an embodiment of the present invention;

FIG. 2 is a block/flow diagram of a method for generating a new molecule that includes particular properties, in accordance with an embodiment of the present invention;

FIG. 3 is a block/flow diagram of a method for training a model for generating new molecules, in accordance with an embodiment of the present invention;

FIG. 4 is a block/flow diagram of a method of manufacturing a new molecule having particular properties, in accordance with an embodiment of the present invention;

FIG. 5 is a block diagram of a computing device that can generate new molecules having particular properties, in accordance with an embodiment of the present invention;

FIG. 6 is a diagram of a neural network architecture that can be used to implement a denoising diffusion implicit model (DDIM), in accordance with an embodiment of the present invention; and

FIG. 7 is a diagram of a deep neural network architecture that can be used to implement a DDIM, in accordance with an embodiment of the present invention.

### DETAILED DESCRIPTION OF PREFERRED EMBODIMENTS

An auxiliary encoder may be used to find a semantic embedding of a three-dimensional (3D) molecule. A semantics-guided equivariant diffusion probabilistic model can then leverage that embedding to control a denoising process. Using the semantics of an input template molecule, the generation of new molecules can be steered toward molecules having one or more desired properties. A machine learning model, such as a classifier or regression model, can be used to predict target molecule attributes in the learned molecular semantic space. By adding weighted combinations of outputs of the target attribution prediction models to the latent embedding vector of the input template molecule, and decoding the result through the learned diffusion probabilistic model, 3D molecules can be generated with desired properties.

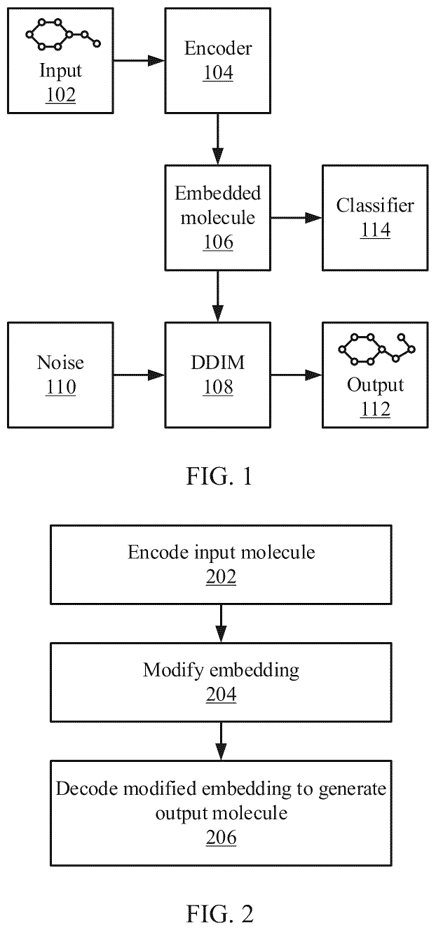

Referring now to FIG. 1, a diagram of molecule generation is shown. An input template molecule 102 includes a definition of a molecule, for example using a graph that includes nodes to represents of the molecule and edges to represent bonds between the atoms. An encoder 104 embeds the original representation of the input template molecule 102 into a latent space, for example generating a vector representation of the input 102 as the embedded molecule 106. The latent space may be interpreted as being analogous to a semantic space for word embedding, where the different dimensions of the latent space represent different characteristics and properties of a molecule.

The embedded molecule 106 may be processed by a denoising diffusion implicit model (DDIM) 108, which is trained to generate an output molecule 112 using a noise input 110. The output 112 is a molecule that is based on the input 102, but may vary in its properties and characteristics. The properties of the output 112 may vary in a manner that is predetermined to help in the generation of molecules that can perform particular functions.

The DDIM 108 and the encoder 104 may be implemented as equivariant graph neural networks (EGNNs). For each layer, given node embeddings h={h₀, . . . , hₙ₋₁} and their corresponding coordinate embeddings x={x₀, . . . , xₙ₋₁}, the layer output is calculated as:

$${m}_{i j} = {ϕ}_{e} ( {h}_{i} , {h}_{j} , {‖ {x}_{i} - {x}_{j} ‖}^{2}$$

$${x}_{i}^{′} = {x}_{i} + C {\sum }_{j \neq i} ( {x}_{i} - {x}_{j} ) {ϕ}_{x} ( {m}_{i j} )$$

$${h}_{i}^{′} = {ϕ}_{h} ( {h}_{i} {\sum }_{j \neq i} {m}_{i j} )$$

The embeddings h′ and x′ are passed to the next layer as input. For DDIM noise estimation, the final output of the EGNN is the noise estimate based on the noisy input (xₜ, hₜ):

$${\hat{ϵ}}_{t}^{( x )} , {\hat{ϵ}}_{t}^{( h )} = {ϵ}_{θ} ( {x}_{t} , {h}_{t} , t ) = EGN {N}_{θ} ( {x}_{t} , {h}_{t} , t )$$

The encoder 104 takes the input molecule (x₀, h₀) and calculates its invariant embedding based on final node embeddings:

$${x}^{′} , {h}^{′} = EGN {N}_{θ} ( {x}_{0} , {h}_{0} )$$

$$z = \frac{1}{n} {\sum }_{i = 0}^{n - 1} {h}_{i}^{′}$$

A denoising diffusion probabilistic model (DDPM) approximates the data distribution p_{θ}(x₀) through a series of latent variables x₁, . . . , x_{T} from the same space as the data x₀, starting from a random noise point x_{T}:

$${p}_{θ} ( {x}_{0} ) = \int p ( {x}_{T} ) {{\prod }^{T}}_{t = 1} {p}_{θ} ( {x}_{t - 1} \vert {x}_{t} ) {dx}_{1 : T}$$

This can be considered as progressively removing the noise from corrupted data x_{T}, which is referred to herein as a reverse or denoising process. The posterior q (x_{1:T}|x₀), or the forward or noising process, is a process of gradually adding noise to x₀ until it eventually becomes random noise x_{T}:

$$q ( {x}_{1 : T} \vert {x}_{0} ) = {\prod }_{t = 1}^{T} q ( {x}_{t} \vert {x}_{t - 1} )$$

The evidence lower bound (ELBO) of log p (x₀) may be maximized. Under Gaussian assumptions, this can be written as:

$${ℒ}_{DDPM} ( {ϵ}_{θ} ) = {\sum }_{t = 1}^{T} {𝔼}_{{x}_{0} , {ϵ}_{t}} {‖ {ϵ}_{θ} ( {x}_{t} , t ) - {ϵ}_{t} ‖}_{2}^{2}$$

where ε_{θ} is a parameterized noise estimator that predicts the noise added to xₜ. The DDIM is trained with this objective, while the reverse process can be calculated deterministically.

An E (n)-equivalent graph neural network (EGNN) can incorporate geometric symmetry into molecular modeling. Given a fully connected graph [symbol] =(vᵢ, eᵢⱼ), i≠j where eᵢⱼ are edges and vᵢ are nodes with a coordinate xᵢ∈ [symbol] ³ (equivariant), a feature hᵢ∈ [symbol] ^{d} (invariant), and a function (x′, h′)=f (x, h), the EGNN ensures the equivariance constraint. Namely, given an orthogonal matrix R ∈ [symbol] ^{3×3} and a translation vector t ∈ [symbol] ³:

$$R {x}^{′} + t , {h}^{′} = f ( R x + t , h )$$

In other words, h is invariant to transformations while x receives the same transformation.

EGNN may be used as noise predictors for the DDPM:

$${\hat{ϵ}}_{t}^{( x )} , {\hat{ϵ}}_{t}^{( h )} = {ϵ}_{θ} ( {x}_{t} , {h}_{t} , t ) = E G N {N}_{θ} ( {x}_{t} , {h}_{t} , t )$$

where \hat{ε}ₜ^{(x)}, \hat{ε}ₜ^{(h)} are equivariant noise on x and invariant noise on h, respectively, following the equivariance constraints above. This ensures the equivariance of the conditional probability p (xₜ₋₁|xₜ). With an invariant prior p (x_{T}), the equivariant process results in an invariant data distribution p_{θ}(X), where the probability of a data point remains the same after transformation. This greatly improves data efficiency and model generalizability.

A semantic embedding may be used to control the generation of the equivariant diffusion model. Let (x₀, h₀) be an input 3D point cloud represented as a fully connected graph and let (x, h) ∈ X be any generic point from the data space X. The encoder 104 may use an equivariant backbone that learns the conditional distribution of the semantics embedding z given the input:

$$q ( z \vert {x}_{0} ) = 𝒩 ( {μ}_{z} , {σ}_{z} )$$

$${μ}_{z} , {σ}_{z} = {Encoder}_{γ} ( {x}_{0} )$$

The embedded molecule 106 is sampled from the distribution and provided to a diffusion decoder to generate a reconstruction of the input. The embedding z is treated as a condition of the diffusion process. Training samples z from q (z|x₀). For most generative tasks, the embedding z=μ_{z} may be used directly. In addition, the encoder 104 can be co-trained with an auxiliary classifier 114 that predicts molecular properties y of interest from z, which can be used to encourage z to carry information about y.

The diffusion decoder ε_{η} predicts the amount of noise εₜ added to (x, h) at each time step in the forward process:

$${\hat{ϵ}}_{t}^{( x )} , {\hat{ϵ}}_{t}^{( h )} = {ϵ}_{θ} ( {x}_{t} , {h}_{t} , z , t ) = {EGNN}_{θ} ( {x}_{t} , {h}_{t} , z , t )$$

Thus, the diffusion objective becomes:

$${L}_{D} ( {ϵ}_{θ} ) = {\sum }_{t = 1}^{T} {𝔼}_{( {x}_{0} , {h}_{0} ) , {ϵ}_{t}^{( x )} , {ϵ}_{t}^{( h )}} [ {‖ {\hat{ϵ}}_{t}^{( x )} - {ϵ}_{t}^{( x )} ‖}_{2}^{2} + [ {‖ {\hat{ϵ}}_{t}^{( h )} - {ϵ}_{t}^{( h )} ‖}_{2}^{2} ]$$

where εₜ^{(x)}, εₜ^{(h)}˜ [symbol] (0,I) and N (0, I) [symbol] is a Gaussian noise distribution. The noise estimator Ee takes both (xₜ, hₜ) and the semantics embedding z as inputs. Here z can be considered as controlling the “direction” of the denoising (i.e. generation) towards the desired semantics. The maximal mutual information (MI) can also be enforced between z and the input, which empowers z to effectively guide and control the generation processes.

Since deterministic reconstruction is needed for an autoencoder-like framework, the DDIM sampling can be used. Starting from the random noise (x_{T}, h_{T}), a reconstruction of (x₀, h₀) can be generated by progressively removing the predicted noise deterministically:

$${x}_{t - 1} = \sqrt{{α}_{t - 1}} ( \frac{{x}_{t} - \sqrt{1 - {α}_{t}} {\hat{ϵ}}_{t}^{( x )}}{\sqrt{{α}_{t}}} ) + \sqrt{1 - {α}_{t - 1}} {\hat{ϵ}}_{t}^{( x )}$$

$${h}_{t - 1} = \sqrt{{α}_{t - 1}} ( \frac{{h}_{t} - \sqrt{1 - {α}_{t}} {\hat{ϵ}}_{t}^{( h )}}{\sqrt{{α}_{t}}} ) + \sqrt{1 - {α}_{t - 1}} {\hat{ϵ}}_{t}^{( h )}$$

This process can in turn be reversed when the time step is sufficiently small. Thus, a noise point (x_{T}, h_{T}) can be deterministically mapped to a data point (x₀, h₀) and vice versa.

To control the scale and shape of z, a regularization term is used on the marginal distribution q(z)=∫ₓ_{₀} q_{γ}(z|x₀) q (x₀) dx₀. Specifically, a samplebased kernel maximum mean discrepancy (MMD) is used on mini-batches of size η to make q (z) approach the shape of a Gaussian prior p (z)= [symbol] (0, I):

$$MMD ( q ( z ) ‖ p ( z ) ) = \frac{1}{{n}^{2}} [ {\sum }_{i \neq j} k ( {z}_{i} , {z}_{j} ) + {\sum }_{i \neq j} k ( {z}_{i}^{′} , {z}_{j}^{′} ) - 2 \sum k ( {z}_{i} , {z}_{j}^{′} ) ]$$

$$1 \leq i , j \leq n$$

where k is the kernel function, zᵢ values are obtained from the data points in the minibatch, and z′ᵢ values are randomly sampled from a Gaussian distribution p (z)= [symbol] (0, I). This objective can be effectively calculated from the sample.

A full training objective is expressed as follows:

$$ℒ = {ℒ}_{D} ( {ϵ}_{θ} ) + β MMD ( q ( z ) ‖ p ( z ) )$$

where β>0 is the regularization strength.

One challenge with the diffusion autoencoder is that the decoder may ignore the embedding z and solely rely on the noise x_{T} for the generation. The above training objective also ensures maximal MI between z and the input x₀. This is motivated by the observation that maximizing MI ensures informative embeddings for encoding structural knowledge in geometric molecular modeling.

For clarity, one character x is used to denote a point in the data space X. When β=1:

$$ℒ = - {ℒ}_{ELBO} - MI ( {x}_{0} , z )$$

$${ℒ}_{ELBO} := - {ℒ}_{D} ( {ϵ}_{θ} ) - {𝔼}_{q ( {x}_{0} )} K L ( q ( z \vert {x}_{0} ) ‖ p ( z ) )$$

where KL is the Kullback-Leibler divergence and [symbol] _{ELBO} is equivalent to the negative ELBO for log p_{θ}(x) under the model assumption. This means that by minimizing [symbol] , the ELBO and the MI can be jointly maximized. In practice, since KL (q (z)∥p(z)) is intractable, it can be approximated with an MMD. Both the KL divergence and the MMD are minimized when q (z)=p(z), thus justifying the approximation.

The model tries to minimize the diffusion loss [symbol] _{D} (ε_{θ}) as well as the KL divergence between q (z) and p (z):

$$ℒ = {ℒ}_{D} ( {ϵ}_{θ} ) + β KL ( q ( z ) ‖ p ( z ) )$$

When β=1, this is equivalent to:

$$ℒ = {ℒ}_{D} ( {ϵ}_{θ} ) + KL ( q ( z ) ‖ p ( z ) ) = \text{} {ℒ}_{D} \text{} - \text{} {𝔼}_{q ( {x}_{0} )} KL ( q ( z ) \vert {x}_{0} ) ‖ p ( z ) ) - \text{} MI \text{} ( {x}_{0} , z ) = \text{} {ℒ}_{ELBO} - MI ( {x}_{0} , z )$$

This means that, by minimizing [symbol] , the ELBO and the MI can be jointly maximized. In practice, since KL (q (z)∥p (z)) is intractable, it can be approximated with an MMD, which gives rise to the approximate objective function:

$$ℒ = {ℒ}_{D} ( {ϵ}_{0} ) + β MMD ( q ( z ) ‖ p ( z ) )$$

The semantics embedding z shares maximal mutual information with the input (x₀, h₀). The semantic embedding can be used for the generation of 3D molecules with desired compositions, structures and properties.

The semantics embedding z of a known molecule (x₀, h₀) can be obtained from the encoder 104 and can be combined with randomly sampled stochastic noise (x′_{T}, h′_{T}) to generate new molecules (x′₀, h′₀).

The values of z dominates the denoising process. Thus, (x′₀, h′₀) should be sufficiently close to (x₀, h₀) because they are generated by the same z, while the random noise (x′_{T}, h′_{T}) accounts for minor variations. Consequently, leveraging molecular generation based on the predominant embedding of a given molecule and its variations facilitates the exploration of compositions, structures, and properties of neighboring molecules associated with the given one.

For any pair of real molecules (x₀⁽ⁱ⁾, h₀⁽ⁱ⁾) and (x₀^{(j)}, h₀^{(j)}, deterministic noise (x_{T}⁽ⁱ⁾, h_{T}⁽ⁱ⁾) and (x_{T}^{(j)}, h_{T}^{(j)}) can be determined from reverse sampling and semantic embedding z⁽ⁱ⁾ and z^{(j)} from the encoder. For λ∈[0,1], linear interpolation is performed for both the noise and the embedding:

$${x}_{T}^{λ} = λ {x}_{T}^{( i )} + ( 1 - λ ) {x}_{T}^{( j )}$$

$${h}_{T}^{λ} = λ {h}_{T}^{( i )} + ( 1 - λ ) {h}_{T}^{( j )}$$

$${z}^{λ} = λ {z}^{( i )} + ( 1 - λ ) {z}^{( j )}$$

New molecules (x₀^{λ}, h₀^{λ}) can then be generated from (x_{T}^{λ}, h_{T}^{λ}) and z^{λ}.

Given a known molecule, a linear framework is used to manipulate the semantic embedding to gain certain properties. A linear regression is trained on the semantic embeddings to predict the property. Given an embedding z, target value y, and the weight and bias of the linear regression (w, b), a new embedding z′ can be generated with the desired property via: s=(y-b-z^{T}w)/w^{T}w; z^{y}=z+sw. The manipulated embedding z′ and the deterministic noise (x_{T}, h_{T}) can be used as input to the DDIM 108 to generate a manipulated molecule (x₀^{y}, h₀^{y}).

Besides generation, the modified semantic embedding z′ can be used to retrieve a molecule from the training set with similar semantics. Specifically, z′ can be compared to the semantics embedding of every molecule in the training set and an example with a highest cosine similarity may be returned. For the comparison of molecular similarity, a cosine similarity may be calculated between the semantics of the two molecules being compared.

A validity metric can be used to evaluate the quality of generated molecules. The bonds of the molecule and their orders are inferred by comparing the atomic distances with the standard range of bond distances. The proportion of valid, unique, and novel molecules in the generated set may be reported, as well as the estimated molecular energy for the generated molecules. Bond lengths are much more irregular in larger and more complicated molecules, making bond order inference difficult. Thus atomic stability may be reported.

Referring now to FIG. 2, a method for generating a new molecule is shown. Block 202 encodes the input template molecule 102 using encoder 104, generating embedding 106. Block 204 modifies the embedding, for example by adding weighted combinations of weight vectors of target attribute prediction models, to create an embedding of a molecule more likely to embody the desired properties. Positive weighting encourages a property, while negative weighting discourages the property. Block 206 decodes the final obtained latent semantic vector embedding through the DDIM 108 to generate an output molecule 112 with the desired properties.

Given 3D molecules (x₀, h₀) and a paired property p, the embedding z can be obtained from the trained encoder 104. A predictive model p=f (z) can be trained to predict p from z. To obtain an embedding that can be translated into a molecule 112 with the modified properties by the DDIM 108, the embedding is updated with the gradient of the predictive model:

$${z}^{′} = z + η \frac{\partial f ( z )}{\partial z}$$

where a positive η encourages the property and a negative η discourages the property.

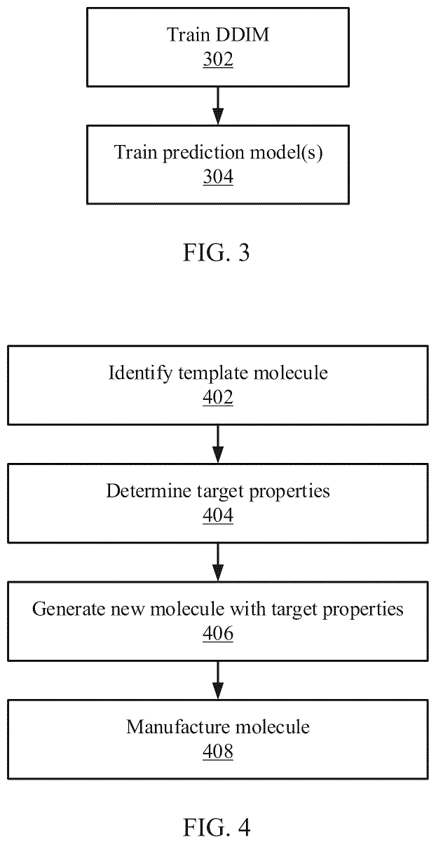

Referring now to FIG. 3, a method for training a molecule generation model is shown. Block 302 trains the DDIM 108 using semantic vectors that represent molecules. The training minimizes a DDIM loss conditioned on the semantic vector and the regularization loss that encourages the aggregated distribution of latent semantic vectors to follow a multivariate Gaussian distribution. Block 304 trains prediction models, such as linear classifiers or regression models, to predict target molecular attributes in the learned molecular semantic vector space.

The training 302 uses training data that includes 3D molecules represented by the coordinates and types of the atoms (x₀, h₀). During training, the input is first corrupted with scheduled noise, resulting in noisy molecules (xₜ, hₜ). The embedding z is calculated from (x₀, h₀) by the encoder 104, then is provided to DDIM 108 to predict noise vectors εₜ^{(x)}, εₜ^{(h)} that are added to (x₀, h₀). The encoder 104 and the DDIM !08 are updated at the same time to minimize the objective function. The learning rate and number of training epochs are selected with a grid search based on cross-validation performance. After training 302, block 304 trains the predictive model to predict molecular property p from the encoder's embedding z of the 3D molecules (x₀, h₀).

Referring now to FIG. 4, a method of making new 3D molecules is shown. Block 402 identifies a template molecule. The template molecule may be one with known properties, such as an existing pharmaceutical that has a known therapeutic effect on the human body. Block 404 then determines target properties for the new molecule. For example, the target molecule may be metabolized too quickly in the human body, or may have binding affinity for a protein that could be higher. The target properties thus indicate how the new molecule should differ in its function from the template molecule.

Block 406 generates the new molecule, with the target properties, as described above. The template molecule is embedded in a latent space by the encoder 104, and the embedding vector is then altered in accordance with the target properties. This altered vector is decoded by the DDIM 108 to generate a specification for the new molecule.

Using the specification for the new molecule, block 408 produces that molecule, or triggers another system to produce the molecule. For example, given a target protein of interest for a pharmaceutical, initial compounds are identified as small molecules that could interact with the target protein. However, these molecules may not be suited for use as a pharmaceutical due to lack of certain desired properties, such as ease of synthesis, toxicity, solubility, permeability, and low affinity to other proteins. The initial compounds may be used as a template, with an embedding vector produced by the encoder 103 being optimized to introduce desired properties when translated by the DDIM 108 to produce new molecules with minimal modifications. This ensures that the interaction to the target protein is maintained while the other properties are emphasized. The same principles can be used for other types of material design, for example promoting the biodegradability of a material while maintaining its overall structure.

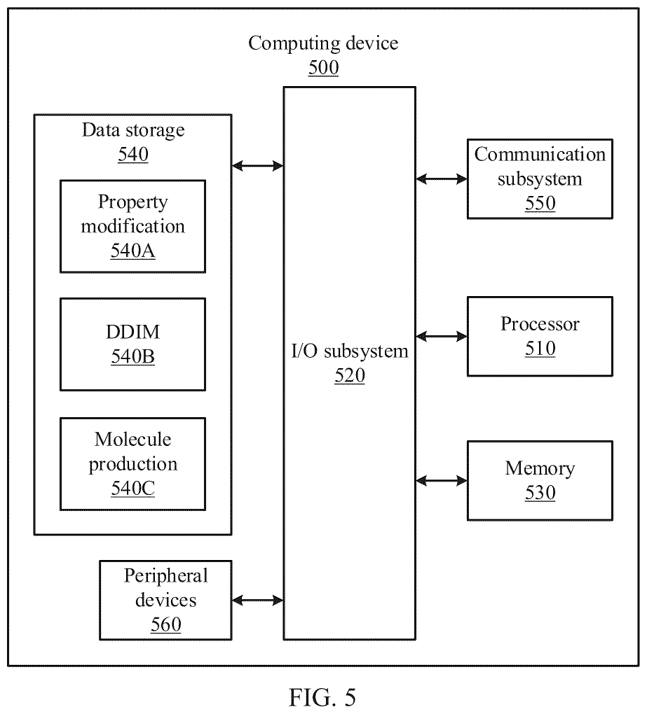

As shown in FIG. 5, the computing device 500 illustratively includes the processor 510, an input/output subsystem 520, a memory 530, a data storage device 540, and a communication subsystem 550, and/or other components and devices commonly found in a server or similar computing device. The computing device 500 may include other or additional components, such as those commonly found in a server computer (e.g., various input/output devices), in other embodiments. Additionally, in some embodiments, one or more of the illustrative components may be incorporated in, or otherwise form a portion of, another component. For example, the memory 530, or portions thereof, may be incorporated in the processor 510 in some embodiments.

The processor 510 may be embodied as any type of processor capable of performing the functions described herein. The processor 510 may be embodied as a single processor, multiple processors, a Central Processing Unit(s) (CPU(s)), a Graphics Processing Unit(s) (GPU(s)), a single or multi-core processor(s), a digital signal processor(s), a microcontroller(s), or other processor(s) or processing/controlling circuit(s).

The memory 530 may be embodied as any type of volatile or non-volatile memory or data storage capable of performing the functions described herein. In operation, the memory 530 may store various data and software used during operation of the computing device 500, such as operating systems, applications, programs, libraries, and drivers. The memory 530 is communicatively coupled to the processor 510 via the I/O subsystem 520, which may be embodied as circuitry and/or components to facilitate input/output operations with the processor 510, the memory 530, and other components of the computing device 500. For example, the I/O subsystem 520 may be embodied as, or otherwise include, memory controller hubs, input/output control hubs, platform controller hubs, integrated control circuitry, firmware devices, communication links (e.g., point-to-point links, bus links, wires, cables, light guides, printed circuit board traces, etc.), and/or other components and subsystems to facilitate the input/output operations. In some embodiments, the I/O subsystem 520 may form a portion of a system-on-a-chip (SOC) and be incorporated, along with the processor 510, the memory 530, and other components of the computing device 500, on a single integrated circuit chip.

The data storage device 540 may be embodied as any type of device or devices configured for short-term or long-term storage of data such as, for example, memory devices and circuits, memory cards, hard disk drives, solid state drives, or other data storage devices. The data storage device 540 can store program code 540A for modifying the properties of an input template molecule, 540B for decoding a new molecule using DDIM, and/or 540C for producing the new molecule. Any or all of these program code blocks may be included in a given computing system. The communication subsystem 550 of the computing device 500 may be embodied as any network interface controller or other communication circuit, device, or collection thereof, capable of enabling communications between the computing device 500 and other remote devices over a network. The communication subsystem 550 may be configured to use any one or more communication technology (e.g., wired or wireless communications) and associated protocols (e.g., Ethernet, InfiniBand®, Bluetooth®, Wi-Fi®, WiMAX, etc.) to effect such communication.

As shown, the computing device 500 may also include one or more peripheral devices 560. The peripheral devices 560 may include any number of additional input/output devices, interface devices, and/or other peripheral devices. For example, in some embodiments, the peripheral devices 560 may include a display, touch screen, graphics circuitry, keyboard, mouse, speaker system, microphone, network interface, and/or other input/output devices, interface devices, and/or peripheral devices.

Of course, the computing device 500 may also include other elements (not shown), as readily contemplated by one of skill in the art, as well as omit certain elements. For example, various other sensors, input devices, and/or output devices can be included in computing device 500, depending upon the particular implementation of the same, as readily understood by one of ordinary skill in the art. For example, various types of wireless and/or wired input and/or output devices can be used. Moreover, additional processors, controllers, memories, and so forth, in various configurations can also be utilized. These and other variations of the processing system 500 are readily contemplated by one of ordinary skill in the art given the teachings of the present invention provided herein.

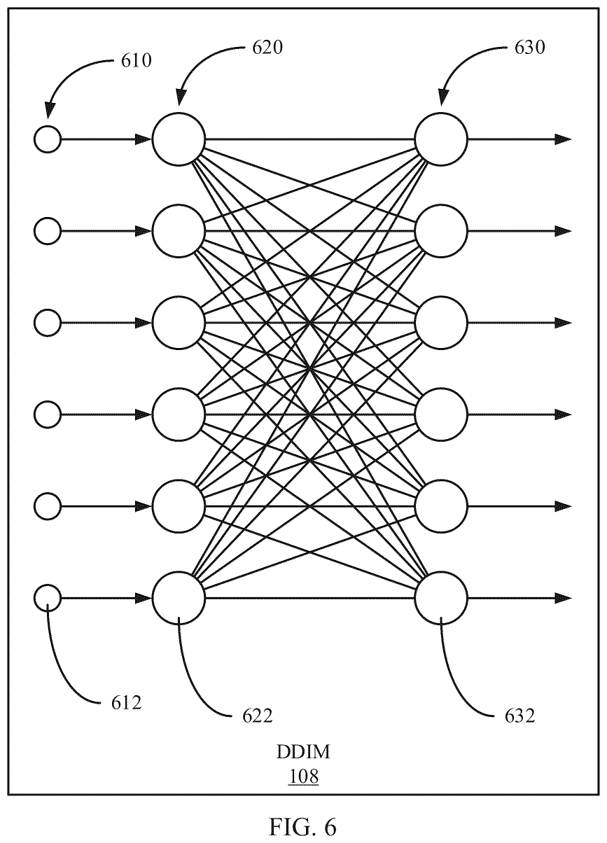

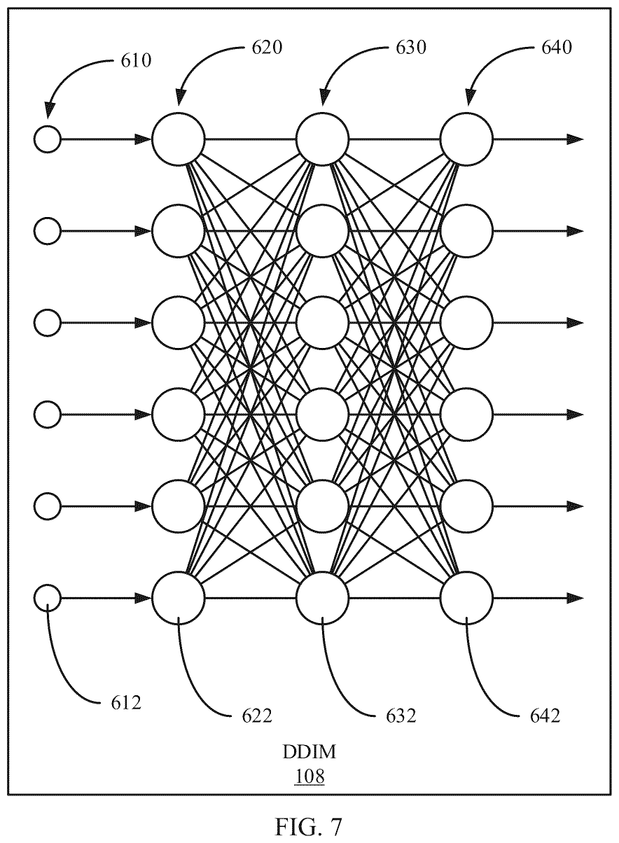

Referring now to FIGS. 6 and 7, exemplary neural network architectures are shown, which may be used to implement parts of the present models, such as the DDIM 108. A neural network is a generalized system that improves its functioning and accuracy through exposure to additional empirical data. The neural network becomes trained by exposure to the empirical data. During training, the neural network stores and adjusts a plurality of weights that are applied to the incoming empirical data. By applying the adjusted weights to the data, the data can be identified as belonging to a particular predefined class from a set of classes or a probability that the input data belongs to each of the classes can be output.

The empirical data, also known as training data, from a set of examples can be formatted as a string of values and fed into the input of the neural network. Each example may be associated with a known result or output. Each example can be represented as a pair, (x, y), where x represents the input data and y represents the known output. The input data may include a variety of different data types, and may include multiple distinct values. The network can have one input node for each value making up the example's input data, and a separate weight can be applied to each input value. The input data can, for example, be formatted as a vector, an array, or a string depending on the architecture of the neural network being constructed and trained.

The neural network “learns” by comparing the neural network output generated from the input data to the known values of the examples, and adjusting the stored weights to minimize the differences between the output values and the known values. The adjustments may be made to the stored weights through back propagation, where the effect of the weights on the output values may be determined by calculating the mathematical gradient and adjusting the weights in a manner that shifts the output towards a minimum difference. This optimization, referred to as a gradient descent approach, is a non-limiting example of how training may be performed. A subset of examples with known values that were not used for training can be used to test and validate the accuracy of the neural network.

During operation, the trained neural network can be used on new data that was not previously used in training or validation through generalization. The adjusted weights of the neural network can be applied to the new data, where the weights estimate a function developed from the training examples. The parameters of the estimated function which are captured by the weights are based on statistical inference.

In layered neural networks, nodes are arranged in the form of layers. An exemplary simple neural network has an input layer 620 of source nodes 622, and a single computation layer 630 having one or more computation nodes 632 that also act as output nodes, where there is a single computation node 632 for each possible category into which the input example could be classified. An input layer 620 can have a number of source nodes 622 equal to the number of data values 612 in the input data 610. The data values 612 in the input data 610 can be represented as a column vector. Each computation node 632 in the computation layer 630 generates a linear combination of weighted values from the input data 610 fed into input nodes 620, and applies a non-linear activation function that is differentiable to the sum. The exemplary simple neural network can perform classification on linearly separable examples (e.g., patterns).

A deep neural network, such as a multilayer perceptron, can have an input layer 620 of source nodes 622, one or more computation layer(s) 630 having one or more computation nodes 632, and an output layer 640, where there is a single output node 642 for each possible category into which the input example could be classified. An input layer 620 can have a number of source nodes 622 equal to the number of data values 612 in the input data 610. The computation nodes 632 in the computation layer(s) 630 can also be referred to as hidden layers, because they are between the source nodes 622 and output node(s) 642 and are not directly observed. Each node 632, 642 in a computation layer generates a linear combination of weighted values from the values output from the nodes in a previous layer, and applies a non-linear activation function that is differentiable over the range of the linear combination. The weights applied to the value from each previous node can be denoted, for example, by w₁, w₂, . . . wₙ₋₁, wₙ. The output layer provides the overall response of the network to the input data. A deep neural network can be fully connected, where each node in a computational layer is connected to all other nodes in the previous layer, or may have other configurations of connections between layers. If links between nodes are missing, the network is referred to as partially connected.

Training a deep neural network can involve two phases, a forward phase where the weights of each node are fixed and the input propagates through the network, and a backwards phase where an error value is propagated backwards through the network and weight values are updated.

The computation nodes 632 in the one or more computation (hidden) layer(s) 630 perform a nonlinear transformation on the input data 612 that generates a feature space. The classes or categories may be more easily separated in the feature space than in the original data space.

Embodiments described herein may be entirely hardware, entirely software or including both hardware and software elements. In a preferred embodiment, the present invention is implemented in software, which includes but is not limited to firmware, resident software, microcode, etc.

Embodiments may include a computer program product accessible from a computer-usable or computer-readable medium providing program code for use by or in connection with a computer or any instruction execution system. A computer-usable or computer readable medium may include any apparatus that stores, communicates, propagates, or transports the program for use by or in connection with the instruction execution system, apparatus, or device. The medium can be magnetic, optical, electronic, electromagnetic, infrared, or semiconductor system (or apparatus or device) or a propagation medium. The medium may include a computer-readable storage medium such as a semiconductor or solid state memory, magnetic tape, a removable computer diskette, a random access memory (RAM), a read-only memory (ROM), a rigid magnetic disk and an optical disk, etc.

Each computer program may be tangibly stored in a machine-readable storage media or device (e.g., program memory or magnetic disk) readable by a general or special purpose programmable computer, for configuring and controlling operation of a computer when the storage media or device is read by the computer to perform the procedures described herein. The inventive system may also be considered to be embodied in a computer-readable storage medium, configured with a computer program, where the storage medium so configured causes a computer to operate in a specific and predefined manner to perform the functions described herein.

A data processing system suitable for storing and/or executing program code may include at least one processor coupled directly or indirectly to memory elements through a system bus. The memory elements can include local memory employed during actual execution of the program code, bulk storage, and cache memories which provide temporary storage of at least some program code to reduce the number of times code is retrieved from bulk storage during execution. Input/output or I/O devices (including but not limited to keyboards, displays, pointing devices, etc.) may be coupled to the system either directly or through intervening I/O controllers.

Network adapters may also be coupled to the system to enable the data processing system to become coupled to other data processing systems or remote printers or storage devices through intervening private or public networks. Modems, cable modem and Ethernet cards are just a few of the currently available types of network adapters.

As employed herein, the term “hardware processor subsystem” or “hardware processor” can refer to a processor, memory, software or combinations thereof that cooperate to perform one or more specific tasks. In useful embodiments, the hardware processor subsystem can include one or more data processing elements (e.g., logic circuits, processing circuits, instruction execution devices, etc.). The one or more data processing elements can be included in a central processing unit, a graphics processing unit, and/or a separate processor- or computing element-based controller (e.g., logic gates, etc.). The hardware processor subsystem can include one or more on-board memories (e.g., caches, dedicated memory arrays, read only memory, etc.). In some embodiments, the hardware processor subsystem can include one or more memories that can be on or off board or that can be dedicated for use by the hardware processor subsystem (e.g., ROM, RAM, basic input/output system (BIOS), etc.).

In some embodiments, the hardware processor subsystem can include and execute one or more software elements. The one or more software elements can include an operating system and/or one or more applications and/or specific code to achieve a specified result.

In other embodiments, the hardware processor subsystem can include dedicated, specialized circuitry that performs one or more electronic processing functions to achieve a specified result. Such circuitry can include one or more application-specific integrated circuits (ASICs), field-programmable gate arrays (FPGAs), and/or programmable logic arrays (PLAs).

These and other variations of a hardware processor subsystem are also contemplated in accordance with embodiments of the present invention.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment. However, it is to be appreciated that features of one or more embodiments can be combined given the teachings of the present invention provided herein.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended for as many items listed.

The foregoing is to be understood as being in every respect illustrative and exemplary, but not restrictive, and the scope of the invention disclosed herein is not to be determined from the Detailed Description, but rather from the claims as interpreted according to the full breadth permitted by the patent laws. It is to be understood that the embodiments shown and described herein are only illustrative of the present invention and that those skilled in the art may implement various modifications without departing from the scope and spirit of the invention. Those skilled in the art could implement various other feature combinations without departing from the scope and spirit of the invention. Having thus described aspects of the invention, with the details and particularity required by the patent laws, what is claimed and desired protected by Letters Patent is set forth in the appended claims.

What is claimed is:

1. A computer-implemented method for molecule generation, comprising:
embedding an input template molecule into a latent space to generate a vector;
decoding the vector using a denoising diffusion implicit model (DDIM) to generate a new molecule specification that is based on the input template molecule; and
producing the new molecule using the new molecule specification.

2. The method of claim 1, further comprising modifying the vector before decoding the vector to change a property of the input template molecule.

3. The method of claim 2, wherein modifying the vector includes adding a weight vector to emphasize or deemphasize the property.

4. The method of claim 3, further comprising generating the weight vector using a predictive model that determines a property of the input template molecule using the vector.

5. The method of claim 1, wherein decoding the vector includes progressively reconstructing the new molecule from a noise input, based on the vector.

6. The method of claim 5, wherein the noise input includes an equivariant noise on nodes of the input template molecule and invariant noise on features of the input template molecule.

7. The method of claim 1, further comprising training the DDIM using a loss function that includes a diffusion loss component.

8. The method of claim 7, wherein the diffusion loss component is expressed as:
$${ℒ}_{D} ( {ϵ}_{θ} ) = {\sum }_{t = 1}^{T} {𝔼}_{( {x}_{0} , {h}_{0} ) , {ϵ}_{t}^{( x )} , {ϵ}_{t}^{( h )}} [ {‖ {\hat{ϵ}}_{t}^{( x )} - {ϵ}_{t}^{( x )} ‖}_{2}^{2} + {‖ {\hat{ϵ}}_{t}^{( h )} - {ϵ}_{t}^{( h )} ‖}_{2}^{2} ]$$
where εₜ^{(x)}, εₜ^{(h)}˜ [symbol] (0, I), [symbol] (0, I) is a Gaussian noise distribution having zero mean and a variance of I, ε_{θ} is a parameterized noise estimator, x₀ is the vector, h₀ is a feature of the vector, and where êₜ^{(x)}, êₜ^{(h)} are equivariant noise on x and invariant noise on h, respectively.

9. The method of claim 7, wherein the loss function further includes a regularization term that is approximated as a maximum mean discrepancy between a marginal distribution of the vector and a randomly sampled Gaussian distribution.

10. The method of claim 1, further comprising jointly training the DDIM and an encoder used to perform the embedding.

11. A system for molecule generation, comprising:
a hardware processor; and
a memory that stores a computer program which, when executed by the hardware processor, causes the hardware processor to:
embed an input template molecule into a latent space to generate a vector;
decode the vector using a denoising diffusion implicit model (DDIM) to generate a new molecule specification that is based on the input template molecule; and
trigger production of the new molecule using the new molecule specification.

12. The system of claim 11, wherein the computer program further causes the hardware processor to modify the vector before decoding the vector to change a property of the input template molecule.

13. The system of claim 12, wherein the computer program further causes the hardware processor to add a weight vector to emphasize or deemphasize the property.

14. The system of claim 13, wherein the computer program further causes the hardware processor to generate the weight vector using a predictive model that determines a property of the input template molecule using the vector.

15. The system of claim 11, wherein the computer program further causes the hardware processor to progressively reconstruct the new molecule from a noise input, based on the vector.

16. The system of claim 15, wherein the noise input includes an equivariant noise on nodes of the input template molecule and invariant noise on features of the input template molecule.

17. The system of claim 11, wherein the computer program further causes the hardware processor to train the DDIM using a loss function that includes a diffusion loss component.

18. The system of claim 17, wherein the diffusion loss component is expressed as:
$${ℒ}_{D} ( {ϵ}_{θ} ) = {\sum }_{t = 1}^{T} {𝔼}_{( {x}_{0} , {h}_{0} ) , {ϵ}_{t}^{( x )} , {ϵ}_{t}^{( h )}} [ {‖ {\hat{ϵ}}_{t}^{( x )} - {ϵ}_{t}^{( x )} ‖}_{2}^{2} + {‖ {\hat{ϵ}}_{t}^{( h )} - {ϵ}_{t}^{( h )} ‖}_{2}^{2} ]$$
where εₜ^{(x)}, εₜ^{(h)}˜ [symbol] (0, I), [symbol] (0, I) is a Gaussian noise distribution having zero mean and a variance of I, ε_{θ} is a parameterized noise estimator, x₀ is the vector, h₀ is a feature of the vector, and where \hat{ε}ₜ^{(x)}, \hat{ε}ₜ^{(h)} are equivariant noise on x and invariant noise on h, respectively.

19. The system of claim 17, wherein the loss function further includes a regularization term that is approximated as a maximum mean discrepancy between a marginal distribution of the vector and a randomly sampled Gaussian distribution.

20. The system of claim 11, wherein the computer program further causes the hardware processor to jointly train the DDIM and an encoder used to embed the input template molecule.
